(19) United States
(12) Patent Application Publication
(10) Pub. No.: US 2022/0336594 A1
(43) Pub. Date: Oct. 20, 2022

(54) TRANSISTOR DEVICE HAVING CHARGE COMPENSATING FIELD PLATES IN-LINE WITH BODY CONTACTS

(71) Applicant: Infineon Technologies Austria AG, Villach (AT)

(72) Inventors: Robert Haase, San Pedro, CA (US); Timothy Henson, Mount Shasta, CA (US)

(21) Appl. No.: 17/230,365

(22) Filed: Apr. 14, 2021

(51) Int. Cl. H01L 29/40; H01L 29/06; H01L 29/49; H01L 29/78; H01L 21/28; H01L 21/765; H01L 29/66

(52) U.S. Cl. CPC H01L 29/407; H01L 29/0696; H01L 29/4933; H01L 29/7813; H01L 21/28052; H01L 21/765; H01L 29/66734

(57) ABSTRACT

A semiconductor device is described. The semiconductor device includes: a plurality of stripe-shaped gates formed in a semiconductor substrate; a plurality of needle-shaped field plate trenches formed in the semiconductor substrate between neighboring ones of the stripe-shaped gates; an insulating layer on the semiconductor substrate; and a plurality of contacts extending through the insulating layer and contacting field plates in the needle-shaped field plate trenches. The contacts have a width that is less than or equal to a width of the needle-shaped field plate trenches, as measured in a first lateral direction which is transverse to a lengthwise extension of the stripe-shaped gates. In the first lateral direction, the contacts are spaced apart from the stripe-shaped gates by a same or greater distance than the needle-shaped field plate trenches. Methods of producing the semiconductor device are also described.

### BACKGROUND

Low RDS_{ON}(on-state resistance) and low energy switching are key parameters for low voltage MOSFET (metal-oxide-semiconductor field-effect transistor) devices. Some low voltage MOSFET devices include charge compensating field plates for realizing lower RDS_{ON}and lower energy switching. The challenge with such devices is to accommodate the source contact, MOS gate, body contact, conducting channel, and charge compensating field plate in the smallest possible cell pitch.

For low voltage MOSFET devices below 40V, a stripe trench structure is typically used with the MOS gate arranged on top of the charge compensating field plate. For medium voltage MOSFETs at 60V and above, a cellular structure with needle field plate provides for an 80% increase in available conduction area compared to equivalent geometry stripe trench designs. In both cases, 2 alignment tolerances are needed to ensure reliable body contact placement which increases cell pitch correspondingly.

Thus, there is a need for an improved power transistor device needle-shaped field plates with reduced cell pitch.

### SUMMARY

According to an embodiment of a semiconductor device, the semiconductor device comprises: a plurality of stripe-shaped gates formed in a semiconductor substrate; a plurality of needle-shaped field plate trenches formed in the semiconductor substrate between neighboring ones of the stripe-shaped gates; an insulating layer on the semiconductor substrate; and a plurality of contacts extending through the insulating layer and contacting field plates in the needle-shaped field plate trenches, wherein the contacts have a width that is less than or equal to a width of the needle-shaped field plate trenches, as measured in a first lateral direction which is transverse to a lengthwise extension of the stripe-shaped gates, wherein in the first lateral direction, the contacts are spaced apart from the stripe-shaped gates by a same or greater distance than the needle-shaped field plate trenches.

According to another embodiment of a semiconductor device, the semiconductor device comprises: a semiconductor substrate; a plurality of stripe-shaped gates formed in the semiconductor substrate, each stripe-shaped gate comprising a gate electrode separated from the semiconductor substrate by a gate dielectric; a plurality of needle-shaped field plate trenches formed in the semiconductor substrate between neighboring ones of the stripe-shaped gates, each needle-shaped field plate trench comprising a field plate separated from the semiconductor substrate by an insulator; source regions of a first conductivity type adjoining body contact regions of a second conductivity type in the semiconductor substrate between neighboring ones of the stripe-shaped gates; an insulating layer on the semiconductor substrate; and a plurality of contacts extending through the insulating layer and contacting the field plates in the needle-shaped field plate trenches, the source regions, and the body contact regions, wherein the contacts have a width that is less than or equal to a width of the needle-shaped field plate trenches, as measured in a first lateral direction which is transverse to a lengthwise extension of the stripe-shaped gates, wherein in the first lateral direction, the contacts are spaced apart from the stripe-shaped gates by a same or greater distance than the needle-shaped field plate trenches such that a cell pitch of the semiconductor device is independent of the contacts.

According to an embodiment of a method of producing a semiconductor device, the method comprises: forming a plurality of needle-shaped field plate trenches in a semiconductor substrate, each needle-shaped field plate trench comprising a field plate separated from the semiconductor substrate by an insulator; forming a plurality of stripe-shaped gates in the semiconductor substrate, each stripe-shaped gate comprising a gate electrode separated from the semiconductor substrate by a gate dielectric, the needle-shaped field plate trenches being disposed between neighboring ones of the stripe-shaped gates; forming source regions of a first conductivity type adjoining body contact regions of a second conductivity type in the semiconductor substrate between neighboring ones of the stripe-shaped gates; forming an insulating layer on the semiconductor substrate; and forming a plurality of contacts that extend through the insulating layer and contact the field plates in the needle-shaped field plate trenches, the source regions, and the body contact regions, wherein the contacts have a width that is less than or equal to a width of the needle-shaped field plate trenches, as measured in a first lateral direction which is transverse to a lengthwise extension of the stripe-shaped gates, wherein in the first lateral direction, the contacts are spaced apart from the stripe-shaped gates by a same or greater distance than the needle-shaped field plate trenches such cell pitch of the semiconductor device is independent of the contacts.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1A illustrates a partial top plan view of a trench gate semiconductor device having a contact configuration that allows for a reduced cell pitch.

FIG. 1B illustrates a cross-sectional view of the trench gate semiconductor device along the line labeled A-A′ in FIG. 1A.

FIG. 1C illustrates a cross-sectional view of the trench gate semiconductor device along the line labeled B-B′ in FIG. 1A.

FIG. 2 illustrates a partial top plan view of a trench gate semiconductor device having a contact configuration that allows for a reduced cell pitch, according to another embodiment.

FIG. 3A illustrates a cross-sectional view along the line labeled A-A′ in FIG. 1A or FIG. 2 and FIG. 3B illustrates a cross-sectional view along the line labeled B-B′ in FIG. 1A or FIG. 2, according to another trench gate semiconductor device embodiment.

FIG. 4A illustrates a cross-sectional view along the line labeled A-A′ in FIG. 1A or FIG. 2 and FIG. 4B illustrates a cross-sectional view along the line labeled B-B′ in FIG. 1A or FIG. 2, according to another trench gate semiconductor device embodiment.

FIG. 5A illustrates a partial top plan view of a planar gate semiconductor device having a contact configuration that allows for a reduced cell pitch.

FIG. 5B illustrates a cross-sectional view of the planar gate semiconductor device along the line labeled A-A′ in FIG. 5A.

FIG. 5C illustrates a cross-sectional view of the planar gate semiconductor device along the line labeled B-B′ in FIG. 5A.

FIG. 6 illustrates a partial cross-sectional view of another embodiment of a planar gate design for the planar gate semiconductor device shown in FIGS. 5A through 5C.

FIG. 7 illustrates a partial cross-sectional view of yet another embodiment of a planar gate design for the planar gate semiconductor device shown in FIGS. 5A through 5C.

### DETAILED DESCRIPTION

The embodiments described provide a semiconductor device having needle-shaped field plates that provide charge compensation and which are in-line with the device body contacts, and corresponding methods of producing the semiconductor device. The body contacts have a width that is less than or equal to a width of the trenches that include the needle-shaped field plates. Also, the body contacts are spaced apart from stripe-shaped gates of the semiconductor device by the same or greater distance than the needle-shaped field plate trenches. Such a configuration allows for a single set of alignment and critical dimension (CD) tolerances between the gate and field plate to be accommodated within the cell pitch where the term ‘cell pitch’ as used herein means the distance across the contact and stripe gates (e.g., W_g+2Sp_fp+W_fp in the figures). Providing the maximum dimension, with alignment tolerance, of the body contact is less than the dimension of the field plate needle, such that the contact alignment and CD variation does not require an additional increase in the cell pitch, thus yielding reduced cell pitch where the term ‘cell pitch’ as used herein means the distance between repeated transistor cells of the semiconductor device. The stripe-shaped gates may be trench or planar gates, as described in more detail later.

Described next with reference to the figures are embodiments of the semiconductor device and corresponding methods of production.

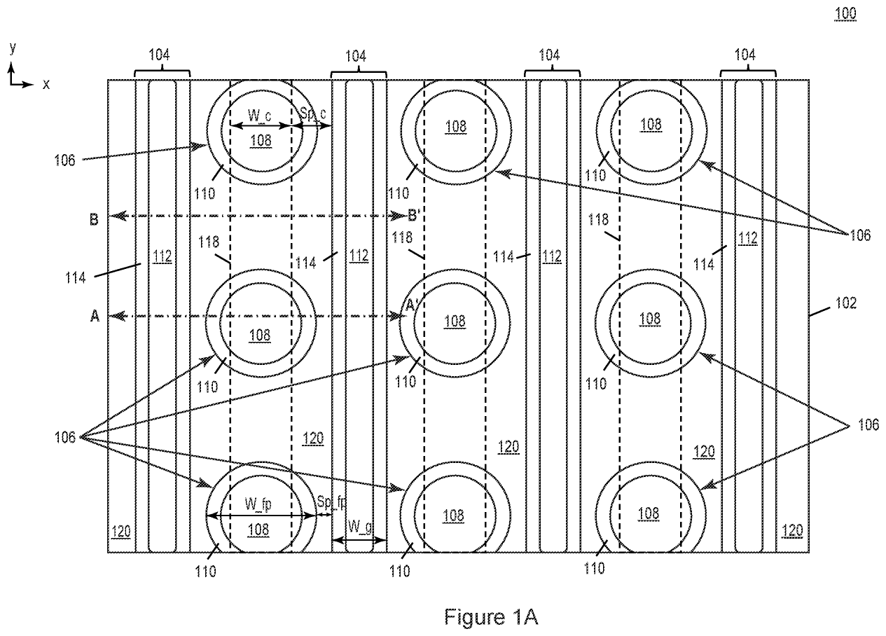

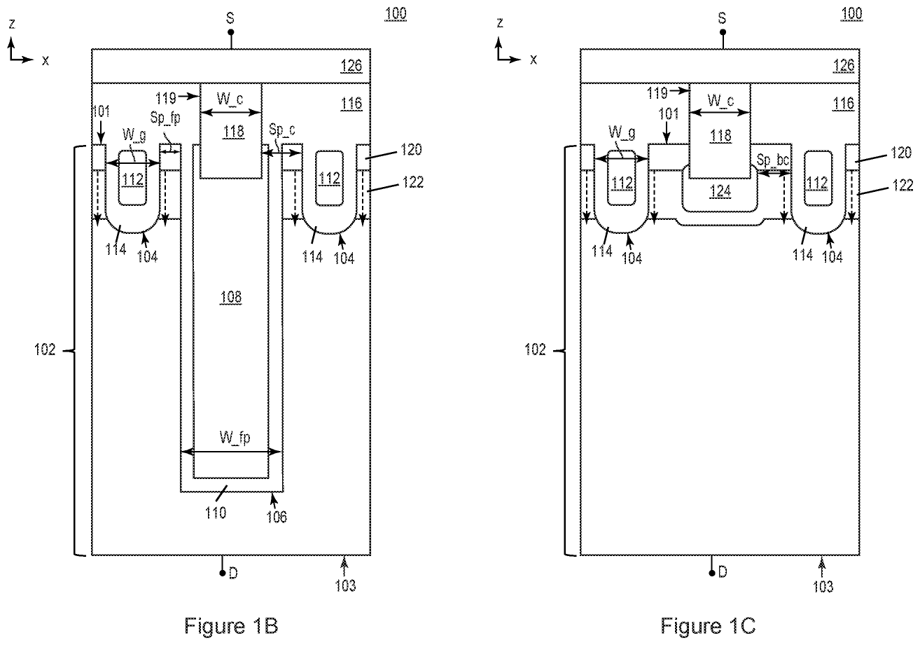

FIG. 1A illustrates a partial top plan view of a trench gate semiconductor device 100 having a body contact configuration that allows for a reduced cell pitch which in turn yields reduced RDS_{ON}. FIG. 1B illustrates a cross-sectional view of the trench gate semiconductor device 100 along the line labeled A-A′ in FIG. 1A. FIG. 1C illustrates a cross-sectional view of the trench gate semiconductor device 100 along the line labeled B-B′ in FIG. 1A.

The semiconductor device 100 may be a low voltage MOSFET device below 40V. The semiconductor device 100 instead may be a medium voltage MOSFET, e.g., at 40V and above. Other device types may utilize the body contact teachings described herein, such as but not limited to IGBTs (insulated gate bipolar transistors), HEMTs (high-electron mobility transistors), etc.

The semiconductor device 100 includes a semiconductor substrate 102. The semiconductor substrate 102 may include one or more of a variety of semiconductor materials that are used to form semiconductor devices such as power MOSFETs, IGBTs, HEMTs, etc. For example, the semiconductor substrate 102 may include silicon (Si), silicon carbide (SiC), germanium (Ge), silicon germanium (SiGe), gallium nitride (GaN), gallium arsenide (GaAs), and the like. The semiconductor substrate 102 may be a bulk semiconductor material or may include one or more epitaxial layers grown on a bulk semiconductor material. In one embodiment, the semiconductor device 100 is a depletion mode transistor device with aggressive feature size reductions.

The semiconductor device 100 further includes stripe-shaped gate trenches 104 formed in the semiconductor substrate 102 and needle-shaped field plate trenches 106 formed in the semiconductor substrate 102 between neighboring ones of the stripe-shaped gate trenches 104. The term ‘needle-shaped’ as used herein means a trench structure that is narrow and long in a depth-wise direction (z direction in FIGS. 1B and 1C) of the semiconductor substrate 102. For example, the needle-shaped field plate trenches 106 may resemble a needle, column or spicule in the depth-wise direction of the semiconductor substrate 102. The term ‘stripe-shaped’ as used herein means a structure having a longest linear dimension in a direction (y direction in FIG. 1A) transverse to the depth-wise direction of the semiconductor substrate 102.

In one embodiment, the needle-shaped field plate trenches 106 are arranged in an orthogonal array in that from a top plan view, the needle-shaped field plate trenches 106 lie at right angles with respect to one another, e.g., as shown in FIG. 1A. However, the needle-shaped field plate trenches 106 may be arranged in other (non-orthogonal) configurations.

A field plate 108 is disposed in each needle-shaped field plate trench 106 and separated from the surrounding semiconductor substrate 102 by an insulator 110 such as a field dielectric, an air gap, a vacuum gap, etc. In a similar manner, a gate electrode 112 is disposed in each stripe-shaped gate trench 104 and separated from the surrounding semiconductor substrate 102 by a gate dielectric 114.

The needle-shaped field plate trenches 106 may extend deeper into the semiconductor substrate 102 than the stripe-shaped gate trenches 104, e.g., as shown in FIG. 1B. The field plates 108 and the gate electrodes 112 may be made from any suitable electrically conductive material such as but not limited to polysilicon, metal, metal alloy, etc. The field plates 108 and the gate electrodes 112 may comprise the same or different electrically conductive material. In the case of a solid material as the insulator 110, the insulator 110 and the gate dielectric 114 may comprise the same or different electrically insulative material, e.g., SiOx and may be formed by one or more common processes such as but not limited to thermal oxidation and/or deposition.

An insulating layer 116 is formed on the semiconductor substrate 102. The insulating layer 116 is not shown in FIG. 1A to provide an unobstructed view of the underlying structures. In one embodiment, the insulating layer 116 is an interlayer dielectric (ILD) such as but not limited to SiOx, SiN, etc. The insulating layer 116 may include one or more sublayers, e.g., a stack of one or more layers of SiOx and one or more layers of SiN.

The semiconductor device 100 further includes body contacts 118 extending through the insulating layer 116. The locations of the body contacts 118 are defined by openings 119 in the insulating layer 116. The body contacts 118 are in contact with the field plates 108 in the needle-shaped field plate trenches 106. The body contacts 118 are in-line with the field plate trenches 106 and shown as dashed rectangles in FIG. 1A to provide an unobstructed view of the underlying structure. The body contacts 118 may be made from any suitable electrically conductive material such as but not limited to polysilicon, metal, metal alloys, metal compounds such as titanium silicide and titanium nitride, etc.

The body contacts 118 have a width ‘W_c’ that is less than or equal to a width ‘W_fp’ of the needle-shaped field plate trenches 106, as measured in a first lateral direction (x direction in FIGS. 1A through 1C) which is transverse to a lengthwise extension (y direction in FIG. 1A) of the stripe-shaped gate trenches 104. According to the example shown in FIGS. 1A and 1B, W_c<W_fp. For example, W_c may be in a range of 100 to 300 nm and W_fp may be in a range of 200 to 400 nm.

In the first lateral direction (x direction in FIGS. 1A through 1C), the body contacts 118 are also spaced apart from the stripe-shaped gate trenches 104 by a same or greater distance (Sp_c ≥Sp_fp) than the needle-shaped field plate trenches 106. Accordingly, the cell pitch of the semiconductor device 100 is not influenced by Sp_c. As a result, cell pitch is defined by the gate width (W_g), the field plate width W_fp, and the field plate-to-gate spacing Sp_fp. According to the example shown in FIGS. 1A and 1B, Sp_c >Sp_fp. For example, Sp_fp may be in a range of 20 to 50 nm and Sp_c may be about 80 nm.

As shown in FIG. 1A, the body contacts may be stripe-shaped. According to this embodiment, the field plates 108 in the needle-shaped field plate trenches 106 disposed between neighboring stripe-shaped gate trenches 104 are contacted by the same body contact 118. For example, in FIG. 1A, the 3 leftmost field plates 108 are contacted by the leftmost body contact 118, the 3 middle field plates 108 are contacted by the middle body contact 118, and the 3 rightmost field plates 108 are contacted by the rightmost body contact 118.

The semiconductor transistor device 100 may also include a gate interconnect structure (not shown) that interconnects the individual gate electrodes 112 in the stripe-shaped gate trenches 104. For example, the gate interconnect structure may include electrically conductive lines separated from the semiconductor substrate 102 by the insulating layer 116 and conductive vias extending through the insulating layer 116 for connecting the overlying electrically conductive lines to the gate electrodes in the underlying stripe-shaped gate trenches 104. The electrically conductive lines and the conductive vias of the gate interconnect structure may be formed within the insulating layer 116, allowing for scaling down to lower voltage nodes.

The semiconductor transistor device 100 may further include a field plate interconnect structure electrically isolated from the gate interconnect structure and which includes the body contacts 118. The field plate interconnect structure and the gate interconnect structure may be at different electric potentials. For example, the field plate interconnect structure may be at source potential and the gate interconnect structure may be at gate potential.

In the case of a transistor device, the body contacts 118 may also contact both source regions 120 of a first conductivity type and adjoining body contact regions 124 of a second conductivity type formed in the semiconductor substrate 102 between neighboring ones of the stripe-shaped gate trenches 104. The body contact regions 124 have a higher average doping concentration than body regions 122 of the second conductivity type. The body contact regions 124 provide an ohmic connection between the body regions 122 and an overlying metallization layer 126, via the body contacts 118. In the embodiments described herein, the first conductivity is n-type and the second conductivity type is p-type for an n-channel device whereas the first conductivity is p-type and the second conductivity type is n-type for a p-channel device.

In the first lateral direction (x direction in FIGS. 1A through 1C), the body contact regions 124 may be spaced apart from the stripe-shaped gate trenches 104 by a same or greater distance (Sp_bc ≥Sp_fp) than the needle-shaped field plate trenches 106. According to the example shown in FIGS. 1A through 1C, Sp_bc>Sp_fp. For example, Sp_bc may be about 60 nm.

The body contact regions 124 may be implanted through the openings 119 in the insulating layer 116 that define the location of the body contacts 118. The body contact regions 124 may be buried below the front main surface 101 of the semiconductor substrate 102, e.g., as shown in FIG. 1C.

The body contacts 118 to the source regions 120 and body contact regions 124 do not add to cell pitch, since the body contacts 118 have the same or smaller width (W_c≤W_fp) than the needle-shaped field plate trenches 106. Accordingly, cell pitch is defined by the spacing Sp_fp between the stripe-shaped gate trenches 104 and the needle-shaped field plate trenches 106.

According to the embodiment illustrated in FIGS. 1A through 1C, the semiconductor device 100 is a vertical transistor device in that the primary current flow path for the device 100 is between the two main opposing surfaces 101, 103 of the semiconductor substrate 102. Accordingly, source and drain terminals S, D are disposed at opposite sides of the semiconductor substrate 102. In the case of a vertical device, transistor channel regions form in the body regions 122 along the stripe-shape gate trenches 104 in the vertical direction (z direction in FIGS. 1B and 1C) when a suitable voltage is applied to the gate electrodes 112, as indicated by the dashed downward facing arrows in FIGS. 1B and 1C.

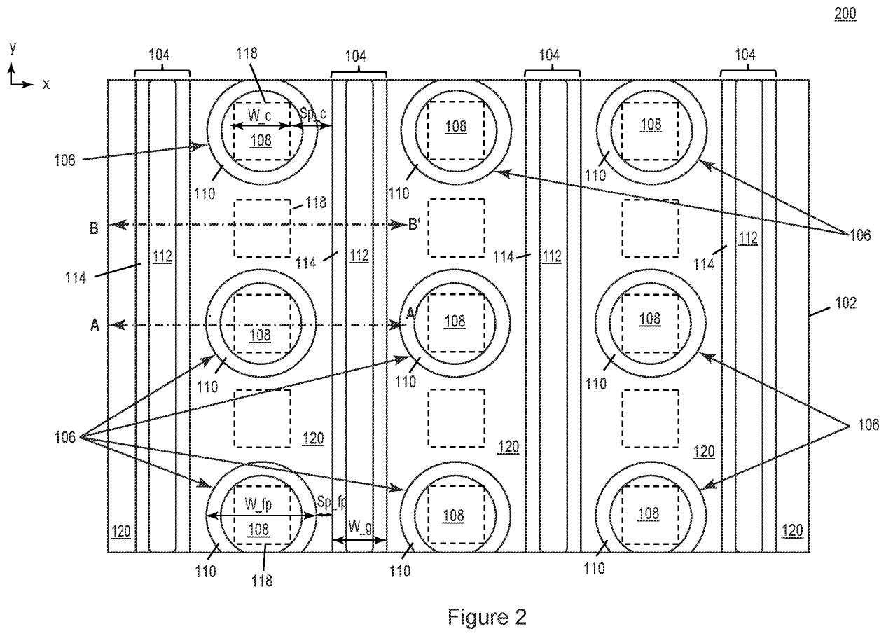

FIG. 2 illustrates a partial top plan view of a trench gate semiconductor device 200 having a contact configuration that allows for a reduced cell pitch, according to another embodiment. The embodiment shown in FIG. 2 is similar to the embodiment shown in FIGS. 1A. Different, however, each of the field plates 108 in the needle-shaped field plate trenches 106 is contacted by a different one of the body contacts 118. That is, instead of the same body contact 118 being in contact with each field plate 108 interposed between a pair of neighboring stripe-shaped gate trenches 104 as shown in FIG. 1A, each field plate 108 is instead contacted by a separate body contact 118 as shown in FIG. 2. According to this embodiment, more than one body contact 118 is provided between each neighboring pair of stripe-shaped gate trenches 104. The body contacts 118 are square shaped in FIG. 2 but may have another shape such as but not limited to circular, hexagonal, rectangular, etc.

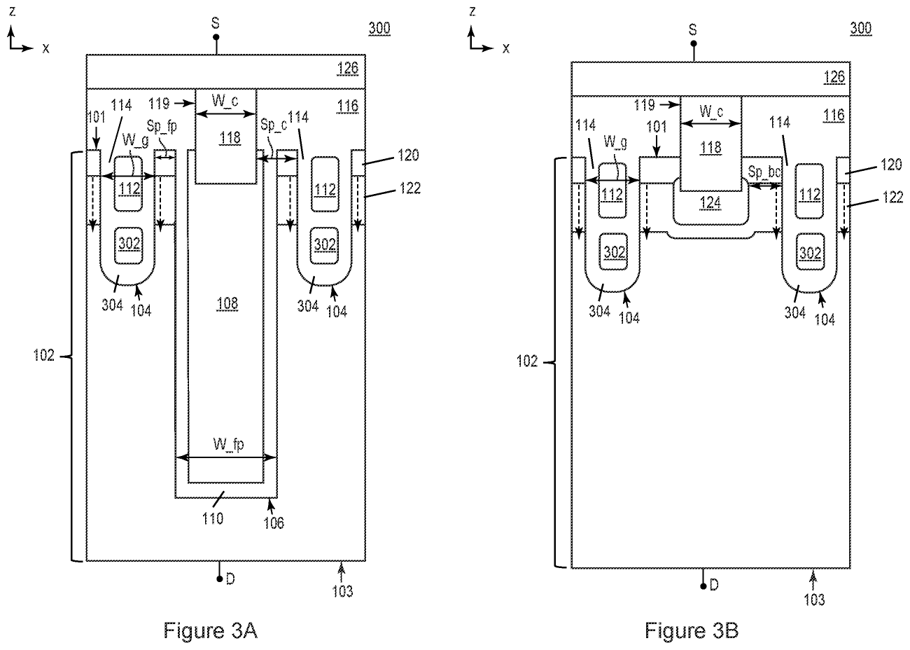

FIGS. 3A and 3B illustrate respective partial cross-sectional views of a trench gate semiconductor device 300 having a contact configuration that allows for a reduced cell pitch, according to another embodiment. The cross-sectional view in FIG. 3A corresponds to the line labelled A-A′ in FIG. 1A or FIG. 2. The cross-sectional view in FIG. 3B corresponds to the line labelled B-B′ in FIG. 1A or FIG. 2. Accordingly, the semiconductor device 300 illustrated in FIGS. 3A and 3B may have a single body contact 118 between each neighboring pair of stripe-shaped gate trenches 104 as shown in FIG. 1A or more than one body contact 118 between each neighboring pair of stripe-shaped gate trenches 104 as shown in FIG. 2.

According to the embodiment illustrated in FIGS. 3A and 3B, the stripe-shaped gate trenches 104 may also include both a gate electrode 112 separated from the semiconductor substrate 102 by a gate dielectric 114 and a shielding electrode 302 below and insulated from the gate electrode 114 by a field dielectric 304. The shielding electrodes 302 shield the gate electrodes 112 from drain (D) potential. The field dielectric 304 and the gate dielectric 114 may comprise the same or different electrically insulative material, e.g., SiOx and may be formed by one or more common processes such as but not limited to thermal oxidation and/or deposition.

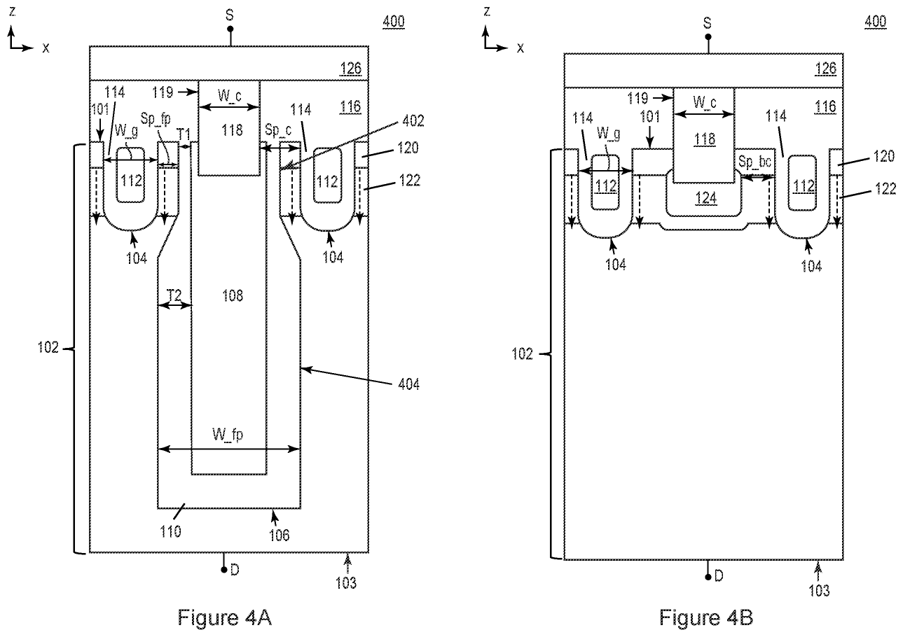

FIGS. 4A and 4B illustrate respective partial cross-sectional views of a trench gate semiconductor device 400 having a contact configuration that allows for a reduced cell pitch, according to another embodiment. The cross-sectional view in FIG. 4A may correspond to the line labelled A-A′ in FIG. 1A or FIG. 2. The cross-sectional view in FIG. 3B may correspond to the line labelled B-B′ in FIG. 1A or FIG. 2. Accordingly, the semiconductor device 400 illustrated in FIGS. 4A and 4B may have a single body contact 118 between each neighboring pair of stripe-shaped gate trenches 104 as shown in FIG. 1A or more than one body contact 118 between each neighboring pair of stripe-shaped gate trenches 104 as shown in FIG. 2.

According to the embodiment illustrated in FIGS. 4A and 4B, the needle-shaped field plate trenches 106 are bottle-shaped with a narrower upper part 402 and a wider lower part 404. The insulator 110 in the needle-shaped field plate trenches 106 and that separates the field plates 108 from the semiconductor substrate 102 may be narrower/thinner (T1) in the narrower upper part 402 of the needle-shaped field plate trenches 106 and wider/thicker (T2) in the wider lower part 404 of the needle-shaped field plate trenches 106. The stripe-shaped gate trenches 104 may be placed closer to the needle-shaped field plate trenches 106 by narrowing/thinning the insulator 110 in the upper part 402 of the needle-shaped field plate trenches 106 as shown in FIG. 3A, further reducing cell pitch.

The device embodiment shown in FIGS. 4A and 4B may be combined with the device embodiments shown in FIGS. 3A and 3B. That is, the semiconductor device 400 shown in FIGS. 4A and 4B may include both a gate electrode 112 and a shielding electrode 302 in the stripe-shaped gate trenches 104.

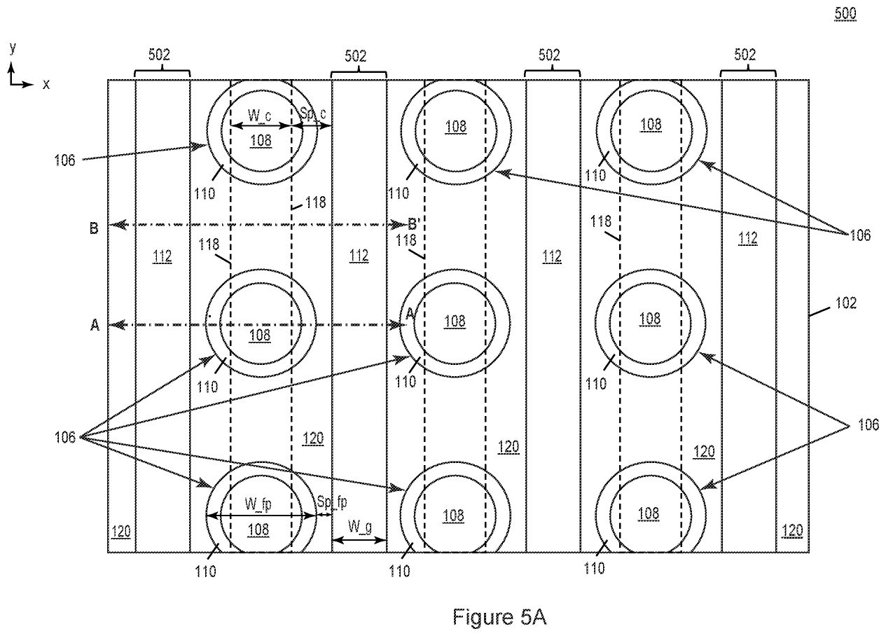

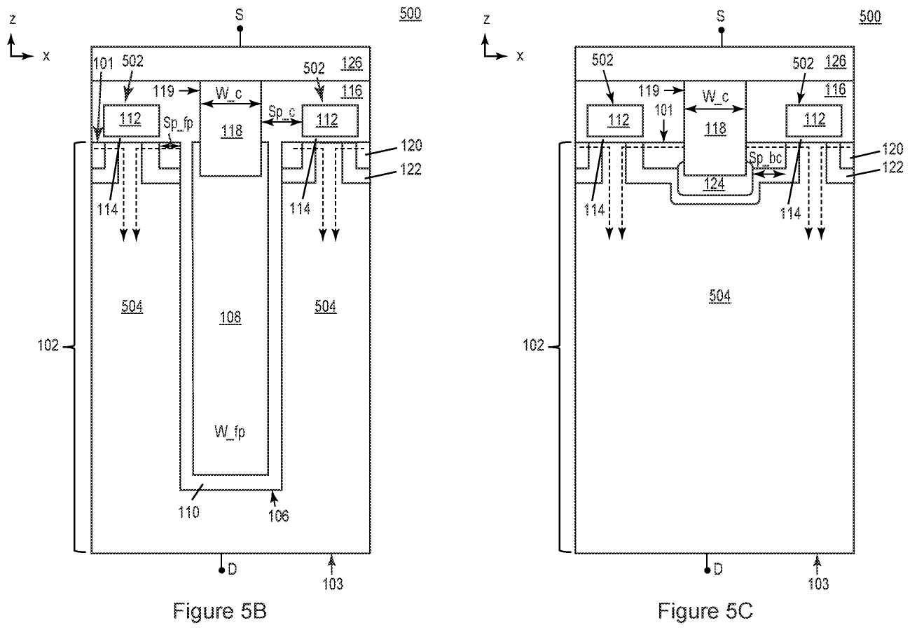

Heretofore, semiconductor device embodiments have been described in the context of trench gates, i.e., gates formed in trenches etched into a semiconductor substrate. However, the embodiments illustrated in FIGS. 1A through 4B may be adapted to planar gate devices by replacing the trench gate structures with planar gate structures. With a planar gate structure, the device gates are formed on the front main surface of a semiconductor substrate instead of in trenches etched into the substrate. Exemplary embodiments of planar gate devices are described next in more detail with reference to FIGS. 5A through 7.

FIG. 5A illustrates a partial top plan view of a planar gate semiconductor device 500 having a body contact configuration that allows for a reduced cell pitch which in turn yields reduced RDS_{ON}. FIG. 5B illustrates a cross-sectional view of the planar gate semiconductor device 500 along the line labeled A-A′ in FIG. 5A. FIG. 5C illustrates a cross-sectional view of the planar gate semiconductor device 500 along the line labeled B-B′ in FIG. 5A.

The embodiment shown in FIGS. 5A through 5C is similar to the embodiment illustrated in FIGS. 1A through 1C. Different, however, the semiconductor device 500 shown in FIGS. 5A through 5C has stripe-shaped planar gates 502 instead of stripe-shaped trench gates 104. The stripe-shaped planar gates 502 each include a stripe-shaped gate electrode 112 separated from the front main surface 101 of the semiconductor substrate 102 by a gate dielectric 114, as shown in FIGS. 5B and 5C. The dashed lines in FIGS. 5B and 5C indicate the current path which has a horizontal component along the gate dielectric 114 and a vertical component in the drift zone 504 of the device 500.

The gate width W_g may be different for the planar gate arrangement compared to the trench gate arrangement. Advantageously, the body proximity to the planar gates 502 is less likely to affect the threshold voltage (Vt) of the device 500 but more likely to pinch off the vertical conduction channel. Hence, Sp_bc may be more critical for a trench gate arrangement because Sp_bc can influence the channel more strongly than in a planar gate arrangement. Accordingly, Sp_c may be smaller for a planar gate arrangement because Sp_bc could be smaller. In general, one or more of the parameter ranges described above for W_g, Sp_fp, W_fp, Sp_c, and Sp_bc may be adjusted accordingly depending on whether a planar gate arrangement or a trench gate arrangement is implemented.

The needle-shaped field plate trenches 106 for the planar gate device 500 may be fabricated as shown in FIG. 5B or instead may have a bottle shape (narrower upper part 402 and wider lower part 404) as shown in FIG. 4A. The planar gate arrangement yields a direct current path down the centre of the semiconductor mesas as indicated by the vertical component of the dashed lines in FIG. 5B and 5C. Such a directed current path allows for a wider field plate implementation since the conduction path does not have to curve around the wider portion of the field plates 108. Accordingly, the bottle-shaped field plate implementation shown in FIG. 4A may be used instead of the field-plate configuration shown in FIG. 5B. Separately or in combination, the planar gate semiconductor device 500 may have a single body contact 118 between each neighboring pair of stripe-shaped planar gates 502 as shown in FIG. 5A or more than one body contact 118 between each neighboring pair of stripe-shaped planar gates 502 as shown in FIG. 2.

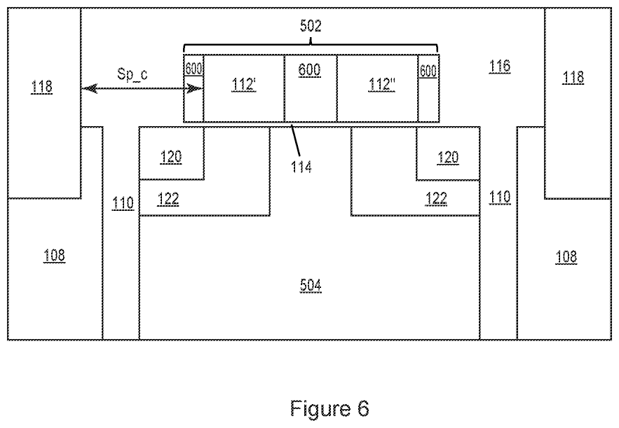

FIG. 6 illustrates a partial cross-sectional view of a planar gate 502. According to this embodiment, the planar gate 502 has a split-gate configuration. That is, the stripe-shaped gate electrode 112 is divided into two separate sections 112′, 112″ separated from one another by an insulating spacer 600 such as an oxide, nitride, etc. The insulating spacer 600 may also cover the sidewalls of the gate electrode sections 112′, 112″.

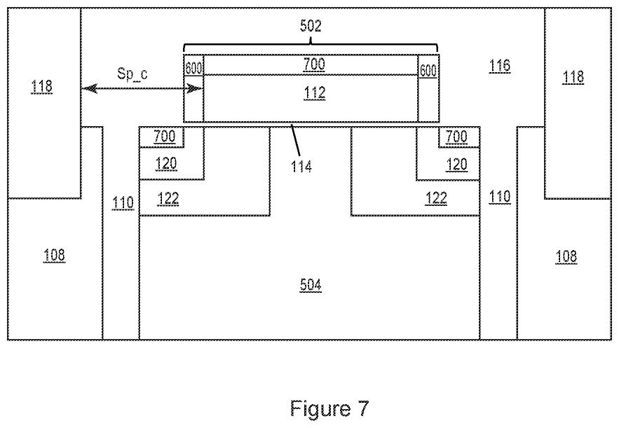

FIG. 7 illustrates a partial cross-sectional view of a planar gate 502, according to another embodiment. Silicide 700 is formed on the upper part of each exposed semiconductor region, including the part of the source regions 120 unprotected by the spacer 600 and the top side of the stripe-shaped gate electrode 112 in the case polysilicon is used for the gate electrode material.

The semiconductor devices 100, 200, 300, 400, 500 described herein may be produced by: forming stripe-shaped planar or trench gates 104/502 and needle-shaped field plate trenches 106 in a semiconductor substrate 102; forming source regions 120, body regions 122 and adjoining body contact regions 124 in the semiconductor substrate 102 between neighboring ones of the stripe-shaped gates 104/502; forming an insulating layer 116 on the semiconductor substrate 102; forming body contacts 118 that extend through the insulating layer 116 and contact field plates 108 in the needle-shaped field plate trenches 106, the source regions 120, and the body contact regions 124; and forming a metallization layer 126 on the insulating layer 116 and in electrical connection with the body contacts 118.

In one embodiment, one or more epitaxial layers are grown on a base semiconductor material to form the semiconductor substrate 102. The needle-shaped field plate trenches 106 are then formed in the semiconductor substrate 102, followed by the stripe-shaped gates 104/502. The body regions 122 and the source regions 120 are then formed in the semiconductor substrate 102 between neighboring ones of the stripe-shaped gates 104/502, e.g., by implantation of dopants of the opposite conductivity type and subsequent annealing. The insulating layer 116 is then formed on the semiconductor substrate 102 and openings 119 are formed in the insulating layer 116. The openings 119 define the location of the body contacts 118.

Dopants of the second conductivity type are implanted into the semiconductor substrate 102 through the openings 119 in the insulating layer 116 and subsequently annealed to form the body contact regions 124. The openings 119 in the insulating layer 116 are then filled with an electrically conductive material to form the body contacts 118. The metallization layer 126 is then deposited on the insulating layer 116 and in contact with the body contacts 118. The metallization layer 126 may comprise any suitable metal or metal alloy such as but not limited to Al, Cu, AlCu, etc. In another embodiment, the stripe-shaped gates 104/502 are formed before the needle-shaped field plate trenches 106. Still other processing sequences may be employed to form the semiconductor devices 100, 200, 300, 400, 500 described herein.

In each case, the body contacts 118 have a width W_c that is less than or equal to the width W_fp of the needle-shaped field plate trenches 106, as measured in a first lateral direction (x direction in FIGS. 1A through 5C) which is transverse to a lengthwise extension (y direction in FIGS. 1A, 2 and 5A) of the stripe-shaped gate trenches 104. In the first lateral direction, the body contacts 118 are also spaced apart from the stripe-shaped gates 104/502 by a same or greater distance (Sp_c≥Sp_fp) than the needle-shaped field plate trenches 106.

Since the body contacts 118 have a width W_c that is less than or equal to the width W_fp of the needle-shaped field plate trenches 106, the body contact implants do not overlap the edge of the needle-shaped field plate trenches 106. Accordingly, cell pitch control is reduced to one alignment tolerance. That is, the body contacts 118 reside within the footprint of the needle-shaped field plate trenches 106 and the body contact implants occur through openings 119 in the insulating layer 116 that define the body contact locations.

Although the present disclosure is not so limited, the following numbered examples demonstrate one or more aspects of the disclosure.

### EXAMPLE 1

A semiconductor device, comprising: a plurality of stripe-shaped gates formed in a semiconductor substrate; a plurality of needle-shaped field plate trenches formed in the semiconductor substrate between neighboring ones of the stripe-shaped gates; an insulating layer on the semiconductor substrate; and a plurality of contacts extending through the insulating layer and contacting field plates in the needle-shaped field plate trenches, wherein the contacts have a width that is less than or equal to a width of the needle-shaped field plate trenches, as measured in a first lateral direction which is transverse to a lengthwise extension of the stripe-shaped gates, wherein in the first lateral direction, the contacts are spaced apart from the stripe-shaped gates by a same or greater distance than the needle-shaped field plate trenches.

### EXAMPLE 2

The semiconductor device of example 1, wherein the contacts also contact both source regions of a first conductivity type and body contact regions of a second conductivity type formed in the semiconductor substrate between neighboring ones of the stripe-shaped gates.

### EXAMPLE 3

The semiconductor device of example 2, wherein in the first lateral direction, the body contact regions are spaced apart from the stripe-shaped gates by a same or greater distance than the needle-shaped field plate trenches.

### EXAMPLE 4

The semiconductor device of any of examples 1 through 3, wherein the contacts are stripe-shaped, and wherein the field plates in the needle-shaped field plate trenches disposed between neighboring stripe-shaped gates are contacted by the same stripe-shaped contact.

### EXAMPLE 5

The semiconductor device of any of examples 1 through 4, wherein each of the field plates in the needle-shaped field plate trenches is contacted by a different one of the contacts.

### EXAMPLE 6

The semiconductor device of any of examples 1 through 5, wherein the stripe-shaped gates each comprise a gate electrode separated from the semiconductor substrate by a gate dielectric in a trench and a shielding electrode below and insulated from the gate electrode in the trench.

### EXAMPLE 7

The semiconductor device of any of examples 1 through 6, wherein the needle-shaped field plate trenches are bottle-shaped with a narrower upper part and a wider lower part.

### EXAMPLE 8

The semiconductor device of example 7, wherein an insulator in the needle-shaped field plate trenches and that separates the field plates from the semiconductor substrate is thinner in the narrower upper part of the needle-shaped field plate trenches and thicker in the wider lower part of the needle-shaped field plate trenches.

### EXAMPLE 9

The semiconductor device of any of examples 1 through 8, wherein the width of the contacts is less than the width of the needle-shaped field plate trenches as measured in the first lateral direction.

### EXAMPLE 10

The semiconductor device of any of examples 1 through 5 and 7 through 9, wherein the stripe-shaped gates are planar gates each comprising a gate electrode separated from a first main surface of the semiconductor substrate by a gate dielectric.

### EXAMPLE 11

The semiconductor device of example 10, wherein the planar gates have a split-gate configuration with each gate electrode divided into two separate sections separated from one another by an insulating spacer.

### EXAMPLE 12. The semiconductor device of example 10 or 11, wherein the gate electrodes comprise polysilicon and silicide is formed on a top side of the gate electrodes.

### EXAMPLE 13

A semiconductor device, comprising: a semiconductor substrate; a plurality of stripe-shaped gates formed in the semiconductor substrate, each stripe-shaped gate comprising a gate electrode separated from the semiconductor substrate by a gate dielectric; a plurality of needle-shaped field plate trenches formed in the semiconductor substrate between neighboring ones of the stripe-shaped gates, each needle-shaped field plate trench comprising a field plate separated from the semiconductor substrate by an insulator; source regions of a first conductivity type adjoining body contact regions of a second conductivity type in the semiconductor substrate between neighboring ones of the stripe-shaped gates; an insulating layer on the semiconductor substrate; and a plurality of contacts extending through the insulating layer and contacting the field plates in the needle-shaped field plate trenches, the source regions, and the body contact regions, wherein the contacts have a width that is less than or equal to a width the needle-shaped field plate trenches, as measured in a first lateral direction which is transverse to a lengthwise extension of the stripe-shaped gates, wherein in the first lateral direction, the contacts are spaced apart from the stripe-shaped gates by a same or greater distance than the needle-shaped field plate trenches such that a cell pitch of the semiconductor device is independent of the contacts.

### EXAMPLE 14

The semiconductor device of example 13, wherein in the first lateral direction, the body contact regions are spaced apart from the stripe-shaped gates by a same or greater distance than the needle-shaped field plate trenches.

### EXAMPLE 15

The semiconductor device of example 13 or 14, wherein the contacts are stripe-shaped, and wherein both the field plates in the needle-shaped field plate trenches and the body contact regions disposed between neighboring stripe-shaped gates are contacted by the same stripe-shaped contact.

### EXAMPLE 16

The semiconductor device of any of examples 13 through 15, wherein each of the field plates in the needle-shaped field plate trenches is contacted by a different one of the contacts, and wherein each of the body contact regions is contacted by a different one of the contacts.

### EXAMPLE 17

The semiconductor device of any of examples 13 through 16, wherein each of the stripe-shaped gates is a trench gate that further comprise a shielding electrode below and insulated from the corresponding gate electrode in a trench.

### EXAMPLE 18

The semiconductor device of any of examples 13 through 17, wherein the needle-shaped field plate trenches are bottle-shaped with a narrower upper part and a wider lower part.

### EXAMPLE 19

The semiconductor device of example 18, wherein the insulator is thinner in the narrower upper part of the needle-shaped field plate trenches and thicker in the wider lower part of the needle-shaped field plate trenches.

### EXAMPLE 20

The semiconductor device of any of examples 13 through 19, wherein the width of the contacts is less than the width of the needle-shaped field plate trenches as measured in the first lateral direction.

### EXAMPLE 21

The semiconductor device of any of examples 13 through 16 and 18 through 20, wherein each of the stripe-shaped gates is a planar gate with the gate electrode separated from a first main surface of the semiconductor substrate by the gate dielectric.

### EXAMPLE 21

A method of producing a semiconductor device, the method comprising: forming a plurality of needle-shaped field plate trenches in a semiconductor substrate, each needle-shaped field plate trench comprising a field plate separated from the semiconductor substrate by an insulator; forming a plurality of stripe-shaped gates in the semiconductor substrate, each stripe-shaped gate comprising a gate electrode separated from the semiconductor substrate by a gate dielectric, the needle-shaped field plate trenches being disposed between neighboring ones of the stripe-shaped gates; forming source regions of a first conductivity type adjoining body contact regions of a second conductivity type in the semiconductor substrate between neighboring ones of the stripe-shaped gates; forming an insulating layer on the semiconductor substrate; and forming a plurality of contacts that extend through the insulating layer and contact the field plates in the needle-shaped field plate trenches, the source regions, and the body contact regions, wherein the contacts have a width that is less than or equal to a width of the needle-shaped field plate trenches, as measured in a first lateral direction which is transverse to a lengthwise extension of the stripe-shaped gates, wherein in the first lateral direction, the contacts are spaced apart from the stripe-shaped gates by a same or greater distance than the needle-shaped field plate trenches such cell pitch of the semiconductor device is independent of the contacts.

### EXAMPLE 22

The method of example 21, wherein in the first lateral direction, the body contact regions are spaced apart from the stripe-shaped gates by a same or greater distance than the needle-shaped field plate trenches.

### EXAMPLE 23

The method of example 22 or 23, wherein the contacts are stripe-shaped, and wherein both the field plates in the needle-shaped field plate trenches and the body contact regions disposed between neighboring stripe-shaped gates are contacted by the same stripe-shaped contact.

### EXAMPLE 25

The method of any of examples 22 through 24, wherein each of the field plates in the needle-shaped field plate trenches is contacted by a different one of the contacts, and wherein each of the body contact regions is contacted by a different one of the contacts.

### EXAMPLE 26

The method of any of examples 22 through 25, wherein the needle-shaped field plate trenches are formed as bottle-shaped with a narrower upper part and a wider lower part.

### EXAMPLE 27

The method of example 26, wherein forming the needle-shaped field plate trenches so as to be bottle-shaped comprises forming the insulator thinner in the narrower upper part of the needle-shaped field plate trenches and thicker in the wider lower part of the needle-shaped field plate trenches.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device, comprising:
a plurality of stripe-shaped gates formed in a semiconductor substrate;
a plurality of needle-shaped field plate trenches formed in the semiconductor substrate between neighboring ones of the stripe-shaped gates;
an insulating layer on the semiconductor substrate; and
a plurality of contacts extending through the insulating layer and contacting field plates in the needle-shaped field plate trenches,
wherein the contacts have a width that is less than or equal to a width of the needle-shaped field plate trenches, as measured in a first lateral direction which is transverse to a lengthwise extension of the stripe-shaped gates,
wherein in the first lateral direction, the contacts are spaced apart from the stripe-shaped gates by a same or greater distance than the needle-shaped field plate trenches.

2. The semiconductor device of claim 1, wherein the contacts also contact both source regions of a first conductivity type and body contact regions of a second conductivity type formed in the semiconductor substrate between neighboring ones of the stripe-shaped gates.

3. The semiconductor device of claim 2, wherein in the first lateral direction, the body contact regions are spaced apart from the stripe-shaped gates by a same or greater distance than the needle-shaped field plate trenches.

4. The semiconductor device of claim 1, wherein the contacts are stripe-shaped, and wherein the field plates in the needle-shaped field plate trenches disposed between neighboring stripe-shaped gates are contacted by the same stripe-shaped contact.

5. The semiconductor device of claim 1, wherein each of the field plates in the needle-shaped field plate trenches is contacted by a different one of the contacts.

6. The semiconductor device of claim 1, wherein the stripe-shaped gates each comprise a gate electrode separated from the semiconductor substrate by a gate dielectric in a trench and a shielding electrode below and insulated from the gate electrode in the trench.

7. The semiconductor device of claim 1, wherein the needle-shaped field plate trenches are bottle-shaped with a narrower upper part and a wider lower part.

8. The semiconductor device of claim 7, wherein an insulator in the needle-shaped field plate trenches and that separates the field plates from the semiconductor substrate is thinner in the narrower upper part of the needle-shaped field plate trenches and thicker in the wider lower part of the needle-shaped field plate trenches.

9. The semiconductor device of claim 1, wherein the width of the contacts is less than the width of the needle-shaped field plate trenches as measured in the first lateral direction.

10. The semiconductor device of claim 1, wherein the stripe-shaped gates are planar gates each comprising a gate electrode separated from a first main surface of the semiconductor substrate by a gate dielectric.

11. The semiconductor device of claim 10, wherein the planar gates have a split-gate configuration with each gate electrode divided into two separate sections separated from one another by an insulating spacer.

12. The semiconductor device of claim 10, wherein the gate electrodes comprise polysilicon and silicide is formed on a top side of the gate electrodes.

13. A semiconductor device, comprising:
a semiconductor substrate;
a plurality of stripe-shaped gates formed in the semiconductor substrate, each stripe-shaped gate comprising a gate electrode separated from the semiconductor substrate by a gate dielectric;
a plurality of needle-shaped field plate trenches formed in the semiconductor substrate between neighboring ones of the stripe-shaped gates, each needle-shaped field plate trench comprising a field plate separated from the semiconductor substrate by an insulator;
source regions of a first conductivity type adjoining body contact regions of a second conductivity type in the semiconductor substrate between neighboring ones of the stripe-shaped gates;
an insulating layer on the semiconductor substrate; and
a plurality of contacts extending through the insulating layer and contacting the field plates in the needle-shaped field plate trenches, the source regions, and the body contact regions,
wherein the contacts have a width that is less than or equal to a width of the needle-shaped field plate trenches, as measured in a first lateral direction which is transverse to a lengthwise extension of the stripe-shaped gates,
wherein in the first lateral direction, the contacts are spaced apart from the stripe-shaped gates by a same or greater distance than the needle-shaped field plate trenches such that a cell pitch of the semiconductor device is independent of the contacts.

14. The semiconductor device of claim 13, wherein in the first lateral direction, the body contact regions are spaced apart from the stripe-shaped gates by a same or greater distance than the needle-shaped field plate trenches.

15. The semiconductor device of claim 13, wherein the contacts are stripe-shaped, and wherein both the field plates in the needle-shaped field plate trenches and the body contact regions disposed between neighboring stripe-shaped gates are contacted by the same stripe-shaped contact.

16. The semiconductor device of claim 13, wherein each of the field plates in the needle-shaped field plate trenches is contacted by a different one of the contacts, and wherein each of the body contact regions is contacted by a different one of the contacts.

17. The semiconductor device of claim 13, wherein each of the stripe-shaped gates is a trench gate that further comprises a shielding electrode below and insulated from the corresponding gate electrode in a trench.

18. The semiconductor device of claim 13, wherein the needle-shaped field plate trenches are bottle-shaped with a narrower upper part and a wider lower part.

19. The semiconductor device of claim 18, wherein the insulator is thinner in the narrower upper part of the needle-shaped field plate trenches and thicker in the wider lower part of the needle-shaped field plate trenches.

20. The semiconductor device of claim 13, wherein the width of the contacts is less than the width of the needle-shaped field plate trenches as measured in the first lateral direction.

21. The semiconductor device of claim 13, wherein each of the stripe-shaped gates is a planar gate with the gate electrode separated from a first main surface of the semiconductor substrate by the gate dielectric.

22. A method of producing a semiconductor device, the method comprising:
forming a plurality of needle-shaped field plate trenches in a semiconductor substrate, each needle-shaped field plate trench comprising a field plate separated from the semiconductor substrate by an insulator;
forming a plurality of stripe-shaped gates in the semiconductor substrate, each stripe-shaped gate comprising a gate electrode separated from the semiconductor substrate by a gate dielectric, the needle-shaped field plate trenches being disposed between neighboring ones of the stripe-shaped gates;
forming source regions of a first conductivity type adjoining body contact regions of a second conductivity type in the semiconductor substrate between neighboring ones of the stripe-shaped gates;
forming an insulating layer on the semiconductor substrate; and
forming a plurality of contacts that extend through the insulating layer and contact the field plates in the needle-shaped field plate trenches, the source regions, and the body contact regions,
wherein the contacts have a width that is less than or equal to a width of the needle-shaped field plate trenches, as measured in a first lateral direction which is transverse to a lengthwise extension of the stripe-shaped gates,
wherein in the first lateral direction, the contacts are spaced apart from the stripe-shaped gates by a same or greater distance than the needle-shaped field plate trenches such cell pitch of the semiconductor device is independent of the contacts.

23. The method of claim 22, wherein in the first lateral direction, the body contact regions are spaced apart from the stripe-shaped gates by a same or greater distance than the needle-shaped field plate trenches.

24. The method of claim 22, wherein the contacts are stripe-shaped, and wherein both the field plates in the needle-shaped field plate trenches and the body contact regions disposed between neighboring stripe-shaped gates are contacted by the same stripe-shaped contact.

25. The method of claim 22, wherein each of the field plates in the needle-shaped field plate trenches is contacted by a different one of the contacts, and wherein each of the body contact regions is contacted by a different one of the contacts.

26. The method of claim 22, wherein the needle-shaped field plate trenches are formed as bottle-shaped with a narrower upper part and a wider lower part.

27. The method of claim 26, wherein forming the needle-shaped field plate trenches so as to be bottle-shaped comprises forming the insulator thinner in the narrower upper part of the needle-shaped field plate trenches and thicker in the wider lower part of the needle-shaped field plate trenches.
